(19) United States
(12) Patent Application Publication
(10) Pub. No.: US 2026/0068405 A1
(43) Pub. Date: Mar. 5, 2026

(54) ELECTRONIC DEVICE

(71) Applicant: Innolux Corporation, Miaoli County (TW)

(72) Inventors: Wei-Sung Lo, Miaoli County (TW); Shih-Fu Liao, Miaoli County (TW); I-AN YAO, Miaoli County (TW)

(73) Assignee: Innolux Corporation, Miaoli County (TW)

(21) Appl. No.: 19/290,321

(22) Filed: Aug. 4, 2025

(30) Foreign Application Priority Data
Sep. 2, 2024 (CN) 202411222679.9

(51) Int. Cl. H10H 29/855; G02F 1/1335

(52) U.S. Cl. CPC H10H 29/855; G02F 1/133512; G02F 1/133514; G02F 1/133541

(57) ABSTRACT

An electronic device of the disclosure includes a first substrate, a circuit layer, a plurality of electronic units, and a circular polarizer. The first substrate has a first surface. The circuit layer is disposed on the first surface. The plurality of electronic units are disposed on the first surface and electrically connected to the circuit layer. The circular polarizer includes a phase retardation film and a linear polarizing film disposed on the phase retardation film, and the linear polarizing film includes a functional region and a redundant region. In a normal direction of the first surface, the redundant region is overlapped with the plurality of electronic units, and the functional region is overlapped with an area of the first substrate not covered by the plurality of electronic units.

### CROSS-REFERENCE TO RELATED APPLICATION

This application claims the priority benefit of China application serial no. 202411222679.9, filed on Sep. 2, 2024. The entirety of the above-mentioned patent application is hereby incorporated by reference herein and made a part of this specification.

### BACKGROUND OF THE DISCLOSURE

### Technical Field

The disclosure relates to an electronic device, and in particular to a display device.

### Description of Related Art

In order to reduce the reflection of light by a circuit layer in an electronic device, the prior art involves attaching a circular polarizer onto an outer surface of a substrate of the electronic device to reduce the reflectivity of the light. However, the arrangement of the circular polarizer affects the light emitted by the electronic units in the electronic device, so that the electronic device of the prior art has relatively poor light extraction efficiency.

### SUMMARY

Some embodiments of the disclosure are directed to an electronic device that may improve light extraction efficiency.

An electronic device provided according to some embodiments of the disclosure includes a first substrate, a circuit layer, a plurality of electronic units, and a circular polarizer. The first substrate has a first surface. The circuit layer is disposed on the first surface. The plurality of electronic units are disposed on the first surface and electrically connected to the circuit layer. The circular polarizer includes a phase retardation film and a linear polarizing film disposed on the phase retardation film, and the linear polarizing film includes a functional region and a redundant region. In a normal direction of the first surface, the redundant region is overlapped with the plurality of electronic units, and the functional region is overlapped with an area of the first substrate not covered by the plurality of electronic units.

Accordingly, the linear polarizing film in the circular polarizer included in the electronic device provided by the disclosure has the functional region and the redundant region, wherein the functional region is overlapped with the area not covered by the plurality of electronic units, and the redundant region is overlapped with the plurality of electronic units. Via the arrangement of the circular polarizer, the functional region is not overlapped with the plurality of electronic units. Therefore, the light extraction efficiency of the electronic device of the disclosure may be improved, and the reflection of light by the circuit layer may be reduced.

In order to make the aforementioned features and advantages of the disclosure more comprehensible, embodiments accompanied with figures are described in detail below.

### BRIEF DESCRIPTION OF THE DRAWINGS

FIG. 1 is a schematic flowchart of a manufacturing method of a circular polarizer of the first embodiment of the disclosure.

FIG. 2 is a schematic flowchart of a manufacturing method of a circular polarizer of the second embodiment of the disclosure.

FIG. 3 is a schematic flowchart of a manufacturing method of a circular polarizer of the third embodiment of the disclosure.

FIG. 4 is a schematic flowchart of a manufacturing method of a circular polarizer of the fourth embodiment of the disclosure.

FIG. 5 is a schematic flowchart of a manufacturing method of a circular polarizer of the fifth embodiment of the disclosure.

FIG. 6A is a partial cross-sectional schematic diagram of an electronic device of the first embodiment of the disclosure.

FIG. 6B is a partial cross-sectional schematic diagram of an electronic device of the second embodiment of the disclosure.

FIG. 6C is a partial cross-sectional schematic diagram of an electronic device of the third embodiment of the disclosure.

FIG. 6D is a partial cross-sectional schematic diagram of an electronic device of the fourth embodiment of the disclosure.

FIG. 6E is a partial cross-sectional schematic diagram of an electronic device of the fifth embodiment of the disclosure.

FIG. 7A is a partial cross-sectional schematic diagram of an electronic device of the sixth embodiment of the disclosure.

FIG. 7B is a partial cross-sectional schematic diagram of an electronic device of the seventh embodiment of the disclosure.

FIG. 7C is a partial cross-sectional schematic diagram of an electronic device of the eighth embodiment of the disclosure.

FIG. 8A is a partial cross-sectional schematic diagram of an electronic device of the ninth embodiment of the disclosure.

FIG. 8B is a partial cross-sectional schematic diagram of an electronic device of the tenth embodiment of the disclosure.

FIG. 8C is a partial cross-sectional schematic diagram of an electronic device of the eleventh embodiment of the disclosure.

FIG. 8D is a partial cross-sectional schematic diagram of an electronic device of the twelfth embodiment of the disclosure.

### DESCRIPTION OF THE EMBODIMENTS

Reference will now be made in detail to the exemplary embodiments of the disclosure, and examples of the exemplary embodiments are illustrated in the accompanying drawings. Wherever possible, the same reference numerals are used in the figures and the descriptions to refer to the same or similar portions.

The disclosure may be understood by referring to the following detailed description in combination with the accompanying drawings. It should be noted that in order to make it easy for readers to understand and for the simplicity of the drawings, many of the drawings in the disclosure depict portions of the electronic device, and certain elements in the drawings are not drawn to actual scale. In addition, the number and the size of elements in the figures are for illustration and are not intended to limit the scope of the disclosure.

Throughout the disclosure, certain words are used to refer to specific elements in the specification and the claims. Those skilled in the art should understand that electronic device manufacturers may refer to the same elements by different names. The specification does not intend to distinguish between elements having the same function but different names. In the specification below and the claims, words such as “include”, “contain”, and “have” are open-ended words, so they should be interpreted to mean “containing but not limited to . . . ” Therefore, when the terms “include”, “contain”, and/or “have” are used in the specification of the disclosure, they specify the presence of the corresponding features, areas, steps, operations, and/or members. However, the presence of one or a plurality of corresponding features, areas, steps, operations, and/or members is not excluded.

The directional terms mentioned herein, such as “upper”, “lower”, “front”, “rear”, “left”, “right”, etc., refer to the directions of the drawings. Accordingly, the directional terms used are illustrative, not limiting, of the disclosure. In the drawings, each drawing depicts general features of methods, structures, and/or materials used in specific embodiments. However, the drawings should not be interpreted as defining or limiting the scope or the nature encompassed by the embodiments. For example, the relative sizes, thicknesses, and locations of various layers, regions, and/or structures may be reduced or exaggerated for clarity.

When a corresponding member (such as a layer or an area) is referred to as being “on another member”, it may be directly on the another member, or other members may be present between the two members. Moreover, when a member is referred to as being “directly on another member”, there are no intervening members between the two members unless otherwise stated in the specification. In addition, when a member is referred to as “on another member”, the two members have a top-down relationship in the top view direction, and the member may be above or below the another member, and the relationship depends on the orientation of the device.

The terms “equal to” or “the same”, “substantially”, or “essentially” are generally interpreted as within 20% of the given value or range, or interpreted as within 10%, 5%, 3%, 2%, 1%, or 0.5% of a given value or range.

Words such as “first” and “second” used in the specification and the claims are used to modify elements, which do not themselves imply and represent that the (or these) elements have any previous ordinal numbers, nor do they imply an order of a certain element with another element, or an order in manufacturing methods. These ordinal numbers are used to clearly distinguish an element having a certain designation from another element having the same designation. The same wording may be not used in the claims and the specification. Accordingly, the first member in the specification may be the second member in the claims.

It should be noted that, in the following embodiments, without departing from the spirit of the disclosure, features in several different embodiments may be replaced, reorganized, and mixed to complete other embodiments. As long as the features of the various embodiments do not violate the spirit of the disclosure or conflict each other, they may be mixed and matched arbitrarily.

The electrical connection described in the disclosure may both refer to direct connection or indirect connection. In the case of a direct connection, the terminals of elements on two circuits are connected directly or to each other by a conductor segment. In the case of indirect connection, there are switches, diodes, capacitors, inductors, other suitable elements, or a combination of the above elements between the terminals of the elements on the two circuits, but the disclosure is not limited thereto.

In the disclosure, the thickness, length, width, and area may be measured using an optical microscope, and the thickness may be measured using a cross-sectional image in an electron microscope, but the disclosure is not limited thereto. In addition, any two values or directions used for comparison may contain certain errors. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

The electronic device of the disclosure may be applied to a display device, a light-emitting device, a backlight device, an antenna device, a sensing device, or a tiling device, or a temporary storage substrate used to assist electronic units in being placed at a specific spacing, but the disclosure is not limited thereto. The electronic device may be a bendable or flexible electronic device. The display device may be a non-self-luminous display device or a self-luminous display device. The antenna device may be a liquid-crystal-type antenna device or a non-liquid-crystal-type antenna device, and the sensing device may be a sensing device sensing capacitance, light, heat energy, or ultrasonic wave, but the disclosure is not limited thereto. The electronic device may include electronic units such as a passive element and an active element, such as a capacitor, a resistor, an inductor, a diode, a transistor, etc. The diode may include a light-emitting diode (LED) or a photodiode. The LED may include, for example, an organic light-emitting diode (OLED), a mini LED, a micro LED, or a quantum dot LED, but the disclosure is not limited thereto. The tiling device may be, for example, a display tiling device or an antenna tiling device, but the disclosure is not limited thereto. It should be noted that the electronic device may be any arrangement and combination of the above, but the disclosure is not limited thereto. Moreover, the shape of the electronic device may be rectangular, circular, polygonal, a shape having a curved edge, or other suitable shapes.

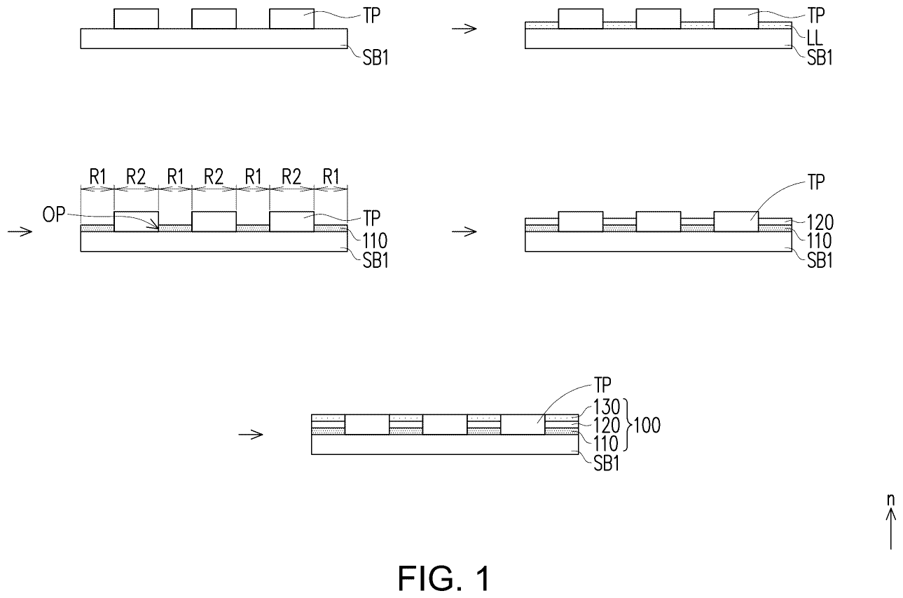

FIG. 1 is a schematic flowchart of a manufacturing method of a circular polarizer of the first embodiment of the disclosure.

Referring to FIG. 1, in the present embodiment, a circular polarizer 100 may be formed by performing the following steps, but the disclosure is not limited thereto.

### Step (1): A Plurality of Patterned Transparent Patterns TP are Formed on a Substrate SB1.

In some embodiments, the plurality of patterned transparent patterns TP may be formed on the substrate SB1 by performing a yellow light process, a nanoimprint process, or other suitable processes, but the disclosure is not limited thereto.

The material of the substrate SB1 may be, for example, glass, plastic, or a combination thereof. For example, the material of the substrate SB1 may include quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), or other suitable materials or a combination of the above materials. In the present embodiment, the material of the substrate SB1 is glass, but the disclosure is not limited thereto. The material of the plurality of patterned transparent patterns TP may be, for example, an organic material or an inorganic material. In the present embodiment, the difference between the refractive index of the plurality of patterned transparent patterns TP and the refractive index of the substrate SB1 is less than 1, so as to reduce the possibility of light being reflected by the interface between the patterned transparent patterns TP and the substrate SB1. In addition, in the present embodiment, the adhesion between the surface of the plurality of patterned transparent patterns TP and a lyotropic liquid crystal is relatively poor, which is described in detail in the following embodiments.

### Step (2): The Circular Polarizer 100 is Formed on the Substrate SB1.

In the present embodiment, the circular polarizer 100 includes a linear polarizing film 110, an intermediate layer 120, and a phase retardation film 130 stacked on each other. In some embodiments, the method of forming the circular polarizer 100 includes the following steps, but the disclosure is not limited thereto.

### Step (2-1): The Linear Polarizing Film 110 is Formed on the Substrate SB1.

In the present embodiment, the material of the linear polarizing film 110 includes a lyotropic liquid crystal LL and a dichroic dye. In some embodiments, the method of forming the linear polarizing film 110 includes the following steps, but the disclosure is not limited thereto.

### Step (2-1): The Lyotropic Liquid Crystal LL is Formed on the Substrate SB1.

First, a coating process may be performed to form a lyotropic liquid-crystal composition on the substrate SB1. The lyotropic liquid-crystal composition includes, for example, the lyotropic liquid crystal LL and a solvent. As described in the above embodiments, since the adhesion between the surface of the plurality of patterned transparent patterns TP and the lyotropic liquid crystal LL is relatively poor, the lyotropic liquid crystal LL in the lyotropic liquid-crystal composition is concentrated in the openings between adjacent patterned transparent patterns TP, and the solvent in the lyotropic liquid-crystal composition may be formed on the surface and in the openings of the plurality of patterned transparent patterns TP.

Then, the solvent in the lyotropic liquid-crystal composition may be removed by performing a suitable drying process, thereby forming the lyotropic liquid crystal LL located in the openings between adjacent patterned transparent patterns TP.

### Step (2-1-2): The Lyotropic Liquid Crystal LL is Dyed.

In some embodiments, the linear polarizing film 110 may be formed by performing a suitable dyeing process to dye the lyotropic liquid crystal LL. The dichroic dye used in the dyeing process may include a suitable organic material, and the disclosure is not limited thereto.

At this point, the production of the linear polarizing film 110 is completed. Although the manufacturing method of the linear polarizing film 110 of the present embodiment is explained by taking the above method as an example, the manufacturing method of the linear polarizing film of the disclosure is not limited thereto. In the present embodiment, the linear polarizing film 110 may include a functional region R1 and a redundant region R2. In detail, the functional region R1 is defined as an area where the linear polarizing film 110 is disposed, and the redundant region R2 is defined as an opening OP of the linear polarizing film 110.

### Step (2-2): The Intermediate Layer 120 is Formed on the Linear Polarizing Film 110.

In some embodiments, the intermediate layer 120 may be formed in the opening by performing a suitable patterning process, so that the intermediate layer 120 is stacked on the linear polarizing film 110, but the disclosure is not limited thereto. The material of the intermediate layer 120 may be, for example, an organic material or an inorganic material. In the present embodiment, the difference between the refractive index of the intermediate layer 120 and the refractive index of the linearly polarizing film 110 is less than 1 to reduce the possibility of light being reflected by the interface between the intermediate layer 120 and the linear polarizing film 110.

### Step (2-3): The Phase Retardation Film 130 is Formed on the Intermediate Layer 120.

In some embodiments, the forming method of the phase retardation film 130 may be similar to the forming method of the lyotropic liquid crystal LL in step (2-1). Specifically, a coating process may be performed to form a lyotropic liquid-crystal composition on the substrate SB1. Due to the characteristic that the adhesion between the surface of the patterned transparent patterns TP and the lyotropic liquid crystal is relatively poor, the lyotropic liquid crystal in the lyotropic liquid-crystal composition is concentrated in the openings between adjacent patterned transparent patterns TP. Then, the solvent in the lyotropic liquid-crystal composition is removed by performing a suitable drying process, thereby forming the phase retardation film 130 located in the openings between adjacent patterned transparent patterns TP, wherein the phase retardation film 130 is stacked on the intermediate layer 120. In the present embodiment, the difference between the refractive index of the phase retardation film 130 and the refractive index of the intermediate layer 120 is less than 1 to reduce the possibility of light being reflected by the interface between the phase retardation film 130 and the intermediate layer 120.

At this point, the production of the circular polarizer 100 is completed. Although the manufacturing method of the circular polarizer 100 of the present embodiment is explained by taking the above method as an example, the manufacturing method of the circular polarizer of the disclosure is not limited thereto.

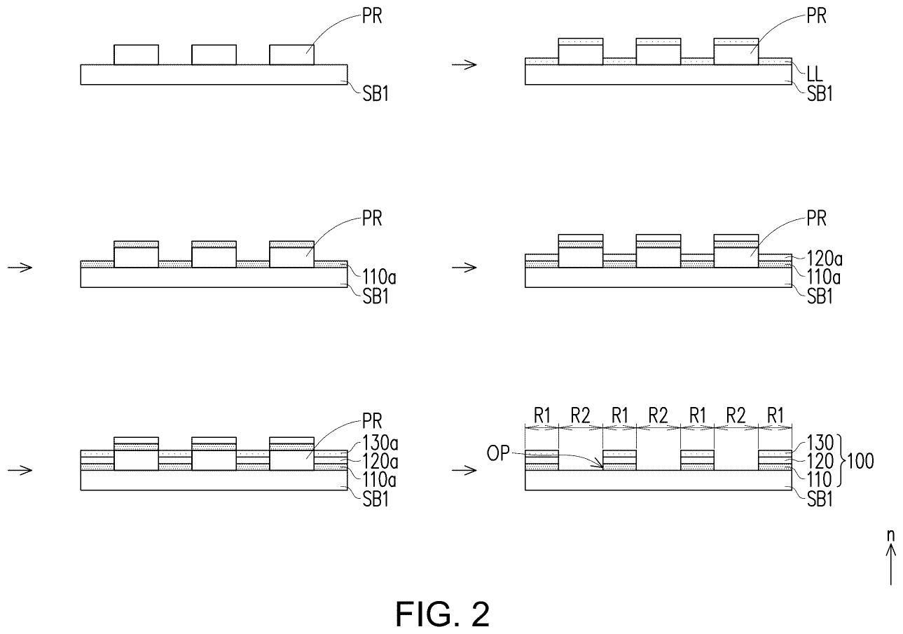

FIG. 2 is a schematic flowchart of a manufacturing method of a circular polarizer of the second embodiment of the disclosure. It should be mentioned that, the embodiment of FIG. 2 may adopt the reference numerals of the embodiment of FIG. 1 and a portion of the contents thereof, wherein the same or similar numerals are used to represent the same or similar elements and descriptions of the same technical contents are omitted.

Referring to FIG. 2, in the present embodiment, the circular polarizer 100 may be formed by performing the following steps, but the disclosure is not limited thereto.

### Step (1a): A Plurality of Patterned Photoresists PR are Formed on the Substrate SB1.

In some embodiments, the plurality of patterned photoresists PR may be formed on the substrate SB1 by performing an exposure and development process, but the disclosure is not limited thereto. The material of the plurality of patterned photoresists PR may be, for example, a suitable organic material, and the disclosure is not limited thereto.

The rest of the description about the substrate SB1 is as provided in the above embodiments, and is not described again here.

### Step (2a): The Circular Polarizer 100 is Formed on the Substrate SB1.

In the present embodiment, the circular polarizer 100 includes the linear polarizing film 110, the intermediate layer 120, and the phase retardation film 130 stacked on each other. In some embodiments, the method of forming the circular polarizer 100 includes the following steps, but the disclosure is not limited thereto.

### Step (2-1a): A Linear Polarizing Film 110a is Formed on the Substrate SB1.

In the present embodiment, the material of the linear polarizing film 110a includes the lyotropic liquid crystal LL and a dichroic dye. In some embodiments, the method of forming the linear polarizing film 110a includes the following steps, but the disclosure is not limited thereto.

Step (2-1-1a): The Lyotropic Liquid Crystal LL is Formed on the Substrate SB1.

First, a coating process may be performed to form a lyotropic liquid-crystal composition on the substrate SB1, wherein the lyotropic liquid-crystal composition covers the plurality of patterned photoresists PR. The lyotropic liquid-crystal composition includes, for example, the lyotropic liquid crystal LL and a solvent.

Then, the solvent in the lyotropic liquid-crystal composition may be removed by performing a suitable drying process, thereby forming the lyotropic liquid crystal LL.

Step (2-1-2a): The Lyotropic Liquid Crystal LL is Dyed.

In some embodiments, the linear polarizing film 110a may be formed by performing a suitable dyeing process to dye the lyotropic liquid crystal LL, wherein the linear polarizing film 110a covers the plurality of patterned photoresists PR. The dichroic dye used in the dyeing process may include a suitable organic material, and the disclosure is not limited thereto.

At this point, the production of the linear polarizing film 110a is completed. Although the manufacturing method of the linear polarizing film 110a of the present embodiment is explained by taking the above method as an example, the manufacturing method of the linear polarizing film of the disclosure is not limited thereto.

### Step (2-2a): An Intermediate Layer 120a is Formed on the Linear Polarizing Film 110a.

In some embodiments, the intermediate layer 120a may be formed on the linear polarizing film 110a by performing a deposition process, a coating process, or other suitable processes, but the disclosure is not limited thereto. The material of the intermediate layer 120a may be, for example, an organic material or an inorganic material. In the present embodiment, the difference between the refractive index of the intermediate layer 120a and the refractive index of the linearly polarizing film 110a is less than 1 to reduce the possibility of light being reflected by the interface between the intermediate layer 120a and the linear polarizing film 110a.

### Step (2-3a): A Phase Retardation Film 130a is Formed on the Intermediate Layer 120a.

In some embodiments, the forming method of the phase retardation film 130a may be similar to the forming method of the lyotropic liquid crystal LL in step (2-1a). Specifically, a coating process may be performed to form a lyotropic liquid-crystal composition on the substrate SB1. Then, a suitable drying process is performed to remove the solvent in the lyotropic liquid-crystal composition, thereby forming the phase retardation film 130a stacked on the intermediate layer 120a. In the present embodiment, the difference between the refractive index of the phase retardation film 130a and the refractive index of the intermediate layer 120a is less than 1 to reduce the possibility of light being reflected by the interface between the phase retardation film 130a and the intermediate layer 120a.

### Step (2-4a): The Plurality of Patterned Photoresists PR are Removed.

In some embodiments, the plurality of patterned photoresists PR may be separated from the substrate SB1 by performing a suitable stripping process to remove the plurality of patterned photoresists PR, but the disclosure is not limited thereto. It should be mentioned that, the linear polarizing film 110a, the intermediate layer 120a, and the phase retardation film 130a located above the plurality of patterned photoresists PR (the plurality of patterned photoresists PR are on the surface away from the substrate SB1) are also removed together with the plurality of patterned photoresists PR in this step. Accordingly, a portion of the linear polarizing film 110a, the intermediate layer 120a, and the phase retardation film 130a are removed in this step to form the linear polarizing film 110, the intermediate layer 120, and the phase retardation film 130 respectively.

At this point, the production of the circular polarizer 100 is completed. Although the manufacturing method of the circular polarizer 100 of the present embodiment is explained by taking the above method as an example, the manufacturing method of the circular polarizer of the disclosure is not limited thereto.

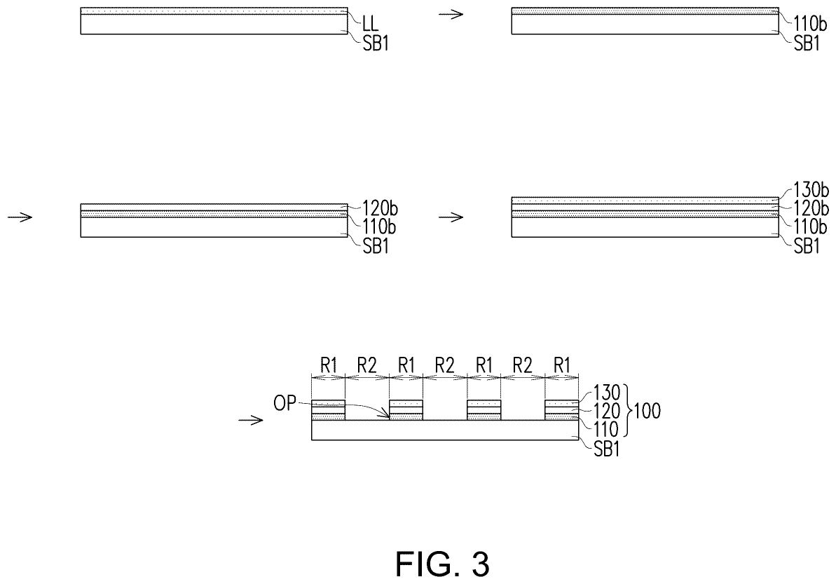

FIG. 3 is a schematic flowchart of a manufacturing method of a circular polarizer of the third embodiment of the disclosure. It should be mentioned that, the embodiment of FIG. 3 may adopt the reference numerals of the embodiment of FIG. 1 and a portion of the contents thereof, wherein the same or similar numerals are used to represent the same or similar elements and descriptions of the same technical contents are omitted.

Referring to FIG. 3, in the present embodiment, the circular polarizer 100 may be formed by performing the following steps, but the disclosure is not limited thereto.

### Step (2b): The Circular Polarizer 100 is Formed on the Substrate SB1.

In the present embodiment, the circular polarizer 100 includes the linear polarizing film 110, the intermediate layer 120, and the phase retardation film 130 stacked on each other. In some embodiments, the method of forming the circular polarizer 100 includes the following steps, but the disclosure is not limited thereto.

### Step (2-1b): A Linear Polarizing Film 110b is Formed on the Substrate SB1.

In the present embodiment, the material of the linear polarizing film 110b includes the lyotropic liquid crystal LL and a dichroic dye. In some embodiments, the method of forming the linear polarizing film 110b includes the following steps, but the disclosure is not limited thereto.

Step (2-1-1b): The Lyotropic Liquid Crystal LL is Formed on the Substrate SB1.

First, a coating process may be performed to form a lyotropic liquid-crystal composition on the substrate SB1. The lyotropic liquid-crystal composition includes, for example, the lyotropic liquid crystal LL and a solvent.

Then, the solvent in the lyotropic liquid-crystal composition may be removed by performing a suitable drying process, thereby forming the lyotropic liquid crystal LL.

Step (2-1-2b): The Lyotropic Liquid Crystal LL is Dyed.

In some embodiments, the linear polarizing film 110b may be formed by performing a suitable dyeing process to dye the lyotropic liquid crystal LL. The dichroic dye used in the dyeing process may include a suitable organic material, and the disclosure is not limited thereto.

At this point, the production of the linear polarizing film 110b is completed. Although the manufacturing method of the linear polarizing film 110b of the present embodiment is explained by taking the above method as an example, the manufacturing method of the linear polarizing film of the disclosure is not limited thereto.

### Step (2-2b): The Intermediate Layer 120b is Formed on the Linear Polarizing Film 110a.

In some embodiments, the intermediate layer 120b may be formed on the linear polarizing film 110b by performing a deposition process, a coating process, or other suitable processes, but the disclosure is not limited thereto. The material of the intermediate layer 120b may be, for example, an organic material or an inorganic material. In the present embodiment, the difference between the refractive index of the intermediate layer 120b and the refractive index of the linearly polarizing film 110b is less than 1 to reduce the possibility of light being reflected by the interface between the intermediate layer 120b and the linear polarizing film 110b.

### Step (2-3b): A Phase Retardation Film 130b is Formed on the Intermediate Layer 120b.

In some embodiments, the forming method of the phase retardation film 130b may be similar to the forming method of the lyotropic liquid crystal LL in step (2-1b). Specifically, a coating process may be performed to form a lyotropic liquid-crystal composition on the substrate SB1. Then, a suitable drying process is performed to remove the solvent in the lyotropic liquid-crystal composition, thereby forming the phase retardation film 130b stacked on the intermediate layer 120b. In the present embodiment, the difference between the refractive index of the phase retardation film 130b and the refractive index of the intermediate layer 120b is less than 1 to reduce the possibility of light being reflected by the interface between the phase retardation film 130b and the intermediate layer 120b.

### Step (2-4b): A Portion of the Linear Polarizing Film 110b, the Intermediate Layer 120b, and the Phase Retardation Film 130b is Removed.

In some embodiments, a portion of the linear polarizing film 110b, the intermediate layer 120b, and the phase retardation film 130b may be removed by performing a suitable patterning process. For example, a portion of the linear polarizing film 110b, the intermediate layer 120b, and the phase retardation film 130b may be removed by performing a laser etching process, but the disclosure is not limited thereto. Accordingly, a portion of the linear polarizing film 110b, the intermediate layer 120b, and the phase retardation film 130b is removed in this step to form the linear polarizing film 110, the intermediate layer 120, and the phase retardation film 130 respectively.

At this point, the production of the circular polarizer 100 is completed. Although the manufacturing method of the circular polarizer 100 of the present embodiment is explained by taking the above method as an example, the manufacturing method of the circular polarizer of the disclosure is not limited thereto.

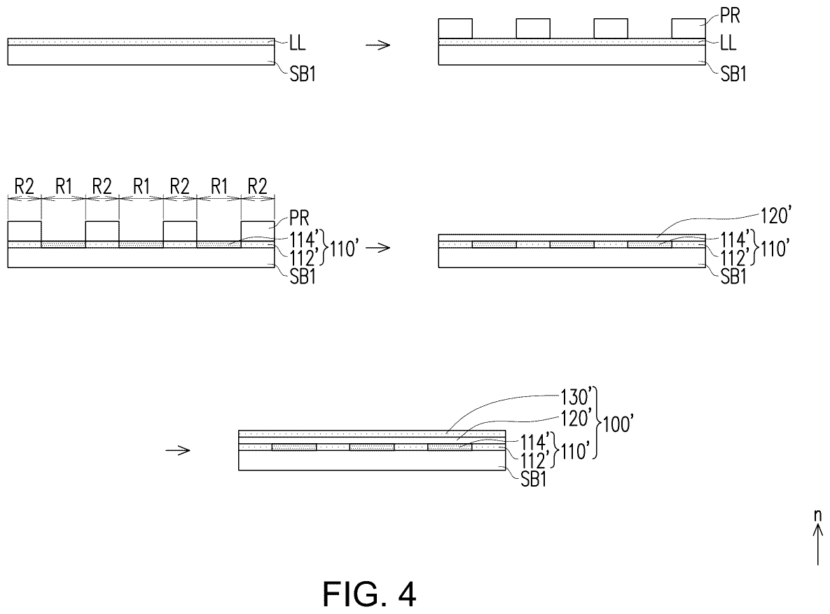

FIG. 4 is a schematic flowchart of a manufacturing method of a circular polarizer of the fourth embodiment of the disclosure. It should be mentioned that, the embodiment of FIG. 4 may adopt the reference numerals of the embodiment of FIG. 1 and a portion of the contents thereof, wherein the same or similar numerals are used to represent the same or similar elements and descriptions of the same technical contents are omitted.

Referring to FIG. 4, in the present embodiment, a circular polarizer 100′ may be formed by performing the following steps, but the disclosure is not limited thereto.

### Step (2c): The Circular Polarizer 100′ is Formed on the Substrate SB1.

In the present embodiment, the circular polarizer 100′ includes a linear polarizing film 110′, an intermediate layer 120′, and a phase retardation film 130′ stacked on each other. In some embodiments, the method of forming the circular polarizer 100′ includes the following steps, but the disclosure is not limited thereto.

### Step (2-1c): The Linear Polarizing Film 110′ is Formed on the Substrate SB1.

In the present embodiment, the material of the linear polarizing film 110′ includes the lyotropic liquid crystal LL and a dichroic dye. In some embodiments, the method of forming the linear polarizing film 110′ includes the following steps, but the disclosure is not limited thereto.

Step (2-1-1c): The Lyotropic Liquid Crystal LL is Formed on the Substrate SB1.

First, a coating process may be performed to form a lyotropic liquid-crystal composition on the substrate SB1. The lyotropic liquid-crystal composition includes, for example, the lyotropic liquid crystal LL and a solvent.

Then, the solvent in the lyotropic liquid-crystal composition may be removed by performing a suitable drying process, thereby forming the lyotropic liquid crystal LL.

Step (2-1-2c): The Plurality of Patterned Photoresists PR are Formed on the Lyotropic Liquid Crystal LL.

In some embodiments, the plurality of patterned photoresists PR may be formed on the surface of the lyotropic liquid crystal LL away from the substrate SB1 by performing an exposure and development process, but the disclosure is not limited thereto. The material of the plurality of patterned photoresists PR may be, for example, a suitable organic material, and the disclosure is not limited thereto.

Step (2-1-3c): The Lyotropic Liquid Crystal LL Exposed by the Plurality of Patterned Photoresists PR is Dyed.

In some embodiments, the lyotropic liquid crystal LL may be dyed by performing a suitable dyeing process using the plurality of patterned photoresists PR to form the linear polarizing film 110′. The dichroic dye used in the dyeing process may include a suitable organic material, and the disclosure is not limited thereto.

Accordingly, in the present embodiment, the linear polarizing film 110′ includes an undyed area 112′ and a dyed area 114′, wherein the undyed area 112′ is overlapped with the plurality of patterned photoresists PR in a normal direction n of the substrate SB1, and the dyed area 114′ is exposed by the plurality of patterned photoresists PR.

At this point, the production of the linear polarizing film 110′ is completed. Although the manufacturing method of the linear polarizing film 110′ of the present embodiment is explained by taking the above method as an example, the manufacturing method of the linear polarizing film of the disclosure is not limited thereto. In the present embodiment, the linear polarizing film 110′ may include the functional region R1 and the redundant region R2. In detail, the functional region R1 is defined as the dyed area 114′ in the linear polarizing film 110′, and the redundant region R2 is defined as the undyed area 112′ in the linear polarizing film 110′.

### Step (2-2c): The Intermediate Layer 120′ is Formed on the Linear Polarizing Film 110′.

It is worth noting that before the intermediate layer 120′ is formed on the linear polarizing film 110′, the plurality of patterned photoresists PR are first removed. In some embodiments, the intermediate layer 120′ may be formed on the linear polarizing film 110′ by performing a deposition process, a coating process, or other suitable processes, but the disclosure is not limited thereto. The material of the intermediate layer 120′ may be, for example, an organic material or an inorganic material. In the present embodiment, the difference between the refractive index of the intermediate layer 120′ and the refractive index of the linearly polarizing film 110′ is less than 1 to reduce the possibility of light being reflected by the interface between the intermediate layer 120′ and the linear polarizing film 110′.

### Step (2-3c): The Phase Retardation Film 130′ is Formed on the Intermediate Layer 120′.

In some embodiments, the forming method of the phase retardation film 130′ may be similar to the forming method of the lyotropic liquid crystal LL in step (2-1-1c). Specifically, a coating process may be performed to form a lyotropic liquid-crystal composition on the substrate SB1. Then, a suitable drying process is performed to remove the solvent in the lyotropic liquid-crystal composition, thereby forming the phase retardation film 130′ stacked on the intermediate layer 120′. In the present embodiment, the difference between the refractive index of the phase retardation film 130′ and the refractive index of the intermediate layer 120′ is less than 1 to reduce the possibility of light being reflected by the interface between the phase retardation film 130′ and the intermediate layer 120′.

At this point, the production of the circular polarizer 100′ is completed. Although the manufacturing method of the circular polarizer 100′ of the present embodiment is explained by taking the above method as an example, the manufacturing method of the circular polarizer of the disclosure is not limited thereto.

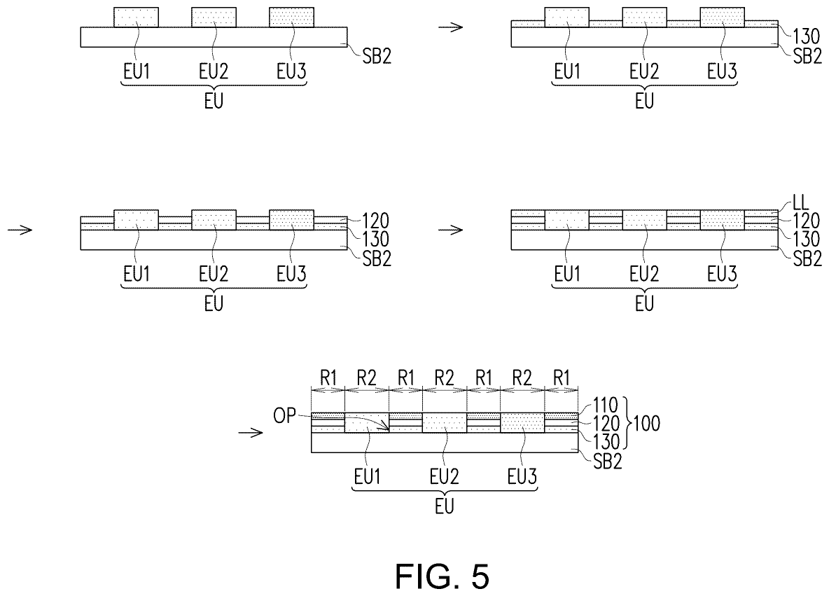

FIG. 5 is a schematic flowchart of a manufacturing method of a circular polarizer of the fifth embodiment of the disclosure. It should be mentioned that, the embodiment of FIG. 5 may adopt the reference numerals of the embodiment of FIG. 1 and a portion of the contents thereof, wherein the same or similar numerals are used to represent the same or similar elements and descriptions of the same technical contents are omitted.

Referring to FIG. 5, in the present embodiment, the circular polarizer 100 may be formed by performing the following steps, but the disclosure is not limited thereto.

### Step (1d): The Plurality of Electronic Units EU are Disposed on the Substrate SB2.

In some embodiments, the plurality of electronic units EU may be disposed on the substrate SB2 by performing mass transfer, but the disclosure is not limited thereto. Any of the plurality of electronic units EU may, for example, emit light of various suitable colors (e.g., red light, green light, and blue light) or UV light, but the disclosure is not limited thereto. In some embodiments, the plurality of electronic units EU may include a self-luminous material. For example, in the present embodiment, the plurality of electronic units EU may be LEDs, including, for example, organic LEDs, micro LEDs, mini LEDs, quantum dot (QD) LEDs, or a combination thereof, but the disclosure is not limited thereto. In some embodiments, the plurality of electronic units EU may include a red light-emitting unit EU1, a green light-emitting unit EU2, and a blue light-emitting unit EU3. That is, the red light-emitting unit EU1, the green light-emitting unit EU2, and the blue light-emitting unit EU3 may respectively emit red light, green light, and blue light. However, the disclosure is not limited thereto. In other embodiments, each of the plurality of electronic units EU may emit blue light or UV light. In the present embodiment, the adhesion between the surface of the plurality of electronic units EU and a lyotropic liquid crystal is relatively poor, which is described in detail in the following embodiments. It is worth noting that, although not shown in FIG. 5, a circuit layer is disposed between the substrate SB2 and the plurality of electronic units EU, wherein the plurality of electronic units EU are electrically connected to the circuit layer.

The material of the substrate SB2 may be, for example, glass, plastic, or a combination thereof. For example, the material of the substrate SB2 may include quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), or other suitable materials or a combination of the above materials. In the present embodiment, the material of the substrate SB2 is glass, but the disclosure is not limited thereto.

### Step (2d): The Circular Polarizer 100 is Formed on the Substrate SB2.

In the present embodiment, the circular polarizer 100 includes the phase retardation film 130, the intermediate layer 120, and the linear polarizing film 110 stacked on each other. In some embodiments, the method of forming the circular polarizer 100 includes the following steps, but the disclosure is not limited thereto.

### Step (2-1d): The Phase Retardation Film 130 is Formed on the Substrate SB2.

In some embodiments, a coating process may be performed to form a lyotropic liquid-crystal composition on the substrate SB2. Due to the characteristic that the adhesion between the surface of the plurality of electronic units EU and the lyotropic liquid crystal is relatively poor, the lyotropic liquid crystal in the lyotropic liquid-crystal composition is concentrated in the openings between adjacent electronic units EU. Then, a suitable drying process is performed to remove the solvent in the lyotropic liquid-crystal composition, thereby forming the phase retardation film 130 located in the openings between adjacent electronic units EU.

### Step (2-2d): The Intermediate Layer 120 is Formed on the Phase Retardation Film 130.

In some embodiments, the intermediate layer 120 may be formed in the openings between adjacent electronic units EU by performing a suitable patterning process, so that the intermediate layer 120 is stacked on the phase retardation film 130, but the disclosure is not limited thereto. The material of the intermediate layer 120 may be, for example, an organic material or an inorganic material. In the present embodiment, the difference between the refractive index of the intermediate layer 120 and the refractive index of the phase retardation film 130 is less than 1 to reduce the possibility of light being reflected by the interface between the intermediate layer 120 and the phase retardation film 130.

### Step (2-3d): The Linear Polarizing Film 110 is Formed on the Intermediate Layer 120.

In the present embodiment, the material of the linear polarizing film 110 includes the lyotropic liquid crystal LL and a dichroic dye. In some embodiments, the method of forming the linear polarizing film 110 includes the following steps, but the disclosure is not limited thereto.

Step (2-3-1d): The Lyotropic Liquid Crystal LL is Formed on the Substrate SB2.

First, a coating process may be performed to form a lyotropic liquid-crystal composition on the substrate SB2. The lyotropic liquid-crystal composition includes, for example, the lyotropic liquid crystal LL and a solvent. As described in the above embodiments, since the adhesion between the surface of the plurality of electronic units EU and the lyotropic liquid crystal LL is relatively poor, the lyotropic liquid crystal LL in the lyotropic liquid-crystal composition is concentrated in the openings between adjacent electronic units EU, and the solvent in the lyotropic liquid-crystal composition may be formed on the surface and in the openings of the plurality of electronic units EU.

Then, the solvent in the lyotropic liquid-crystal composition may be removed by performing a suitable drying process, thereby forming the lyotropic liquid crystal LL located in the openings between the plurality of adjacent electronic units EU.

Step (2-3-2d): The Lyotropic Liquid Crystal LL is Dyed.

In some embodiments, the linear polarizing film 110 may be formed by performing a suitable dyeing process to dye the lyotropic liquid crystal LL. The dichroic dye used in the dyeing process may include a suitable organic material, and the disclosure is not limited thereto. In the present embodiment, the difference between the refractive index of the linear polarizing film 110 and the refractive index of the intermediate layer 120 is less than 1 to reduce the possibility of light being reflected by the interface between the linear polarizing film 110 and the intermediate layer 120.

At this point, the production of the linear polarizing film 110 is completed. Although the manufacturing method of the linear polarizing film 110 of the present embodiment is explained by taking the above method as an example, the manufacturing method of the linear polarizing film of the disclosure is not limited thereto.

At this point, the production of the circular polarizer 100 is completed. Although the manufacturing method of the circular polarizer 100 of the present embodiment is explained by taking the above method as an example, the manufacturing method of the circular polarizer of the disclosure is not limited thereto.

In the manufacturing method of the circular polarizer 100 or the circular polarizer 100′ provided in the above embodiments, the linear polarizing film 110 or the linear polarizing film 110′ is formed by drying and dyeing the lyotropic liquid-crystal composition. The lyotropic liquid-crystal composition may be patterned before or after drying to form the functional region R1 and the redundant region R2 respectively; or after drying, the exposed area of the lyotropic liquid-crystal composition may be dyed using the plurality of patterned photoresists PR to form the functional region R1 and the redundant region R2 respectively. Therefore, when the circular polarizer 100 or the circular polarizer 100′ provided in the above embodiments is applied to an electronic device, the electronic device may reduce the reflection of light by the circuit layer, and the light extraction efficiency thereof may be improved. The description of the electronic device is introduced in the following embodiments.

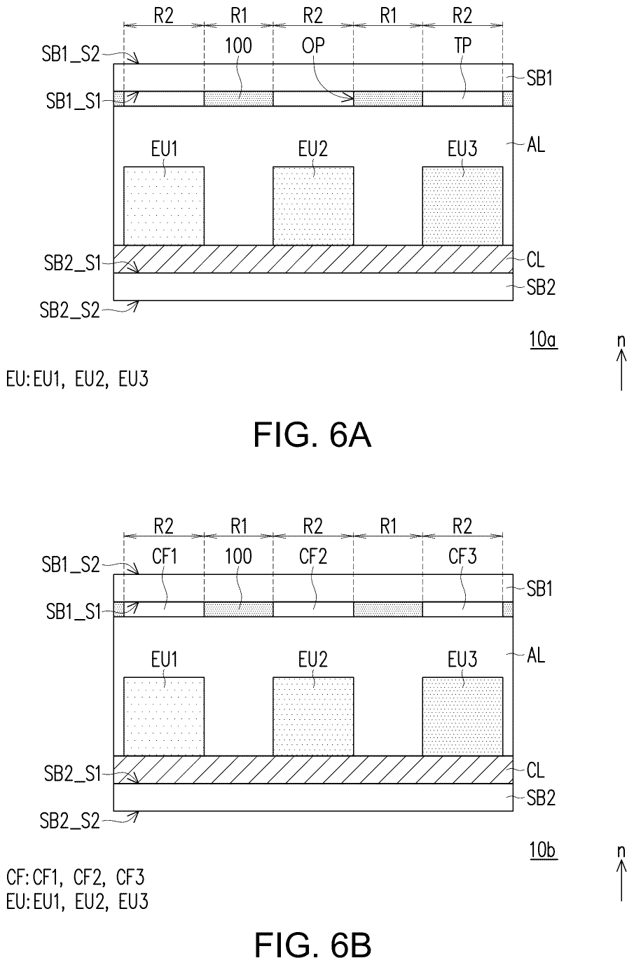

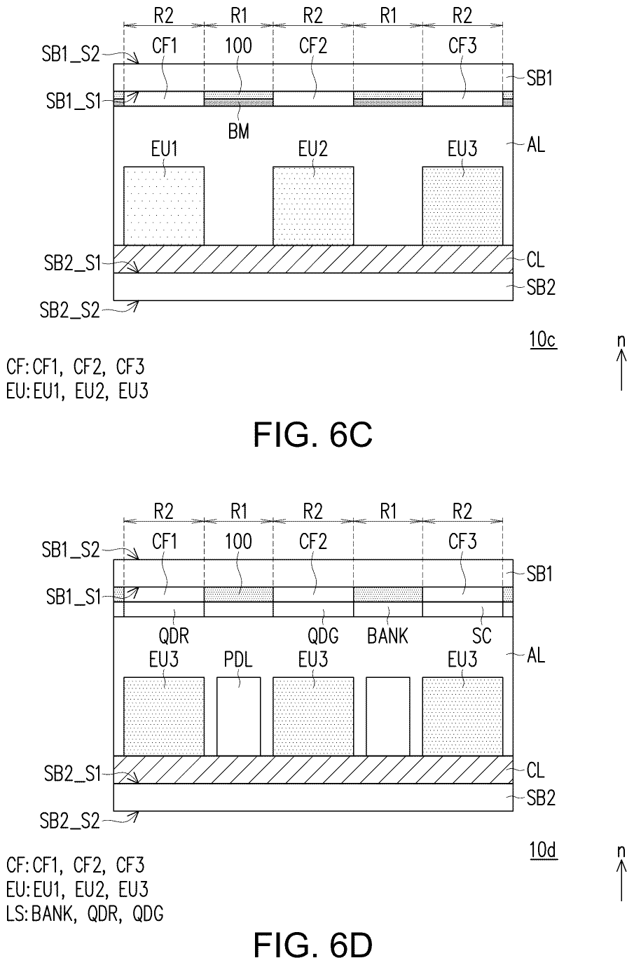

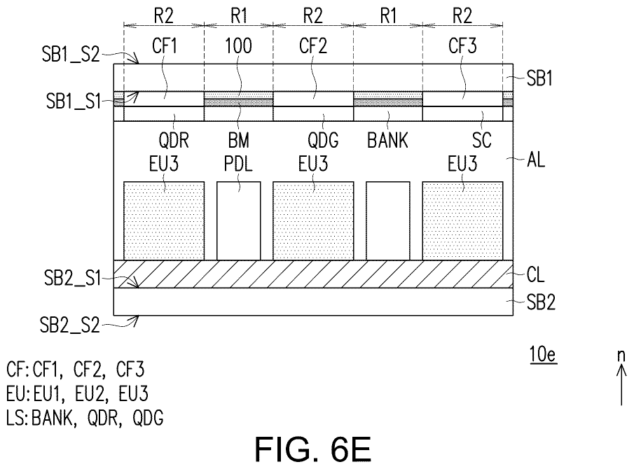

FIG. 6A is a partial cross-sectional schematic diagram of an electronic device of the first embodiment of the disclosure. It should be mentioned that, the embodiment of FIG. 6A may adopt the reference numerals of the embodiment of FIG. 1 and a portion of the contents thereof, wherein the same or similar numerals are used to represent the same or similar elements and descriptions of the same technical contents are omitted.

Please refer to FIG. 6A. In the present embodiment, an electronic device 10a includes the substrate SB1, the plurality of patterned transparent patterns TP, the circular polarizer 100, the substrate SB2, a circuit layer CL, and the plurality of electronic units EU.

The substrate SB1 has, for example, a first surface SB1_S1 and a second surface SB1_S2 opposite to the first surface SB1_S1. The rest of the description about the substrate SB1 is as provided in the above embodiments, and is not described again here.

The plurality of patterned transparent patterns TP are, for example, disposed on the first surface SB1_S1 of the substrate SB1. In the present embodiment, there are openings between adjacent patterned transparent patterns TP. The rest of the description of the plurality of patterned transparent patterns TP is as provided in the above embodiments, and is not described again here.

The circular polarizer 100 is, for example, disposed on the first surface SB1_S1 of the substrate SB1, and is disposed, for example, in the openings of the plurality of patterned transparent patterns TP. Viewed from another perspective, the circular polarizer 100 also includes the openings OP. In the present embodiment, the circular polarizer 100 includes the linear polarizing film 110, the intermediate layer 120, and the phase retardation film 130 stacked on each other. In detail, the linear polarizing film 110 is, for example, disposed on the first surface SB1_S1 of the substrate SB1, the intermediate layer 120 is, for example, disposed on the surface of the linear polarizing film 110 away from the substrate SB1, and the phase retardation film 130 is, for example, disposed on the surface of the intermediate layer 120 away from the linear polarizing film 110.

The polarizing film 110 includes, for example, lyotropic liquid crystal and dichroic dye. In the present embodiment, the linear polarizing film 110 includes the functional region R1 and the redundant region R2. In detail, the linear polarizing film 110 includes the functional region R1 changing light into linearly polarized light and the redundant region R2 of the remaining regions, wherein the functional region R1 is defined as an area where the linear polarizing film 110 is disposed, and the redundant region R2 is defined as the openings OP of the linear polarizing film 110.

The phase retardation film 130 includes, for example, lyotropic liquid crystal. In some embodiments, the phase retardation film 130 includes a quarter-wave plate, but the disclosure is not limited thereto.

The rest of the description about the circular polarizer 100 is as provided in the above embodiments, and is not described again here.

The substrate SB2 has, for example, a first surface SB2_S1 and a second surface SB2_S2 opposite to the first surface SB2_S1. In the present embodiment, the first surface SB2_S1 of the substrate SB2 faces the first surface SB1_S1 of the substrate SB1. Therefore, the circular polarizer 100 is disposed between the substrate SB2 and the substrate SB1, but the disclosure is not limited thereto. The rest of the description about the substrate SB2 is as provided in the above embodiments, and is not described again here.

The circuit layer CL is, for example, disposed on the first surface SB2_S1 of the substrate SB2. In some embodiments, the circuit layer CL may include a plurality of transistors (not shown), a plurality of wires (not shown), and a plurality of insulating layers (not shown), but the disclosure is not limited thereto.

The plurality of electronic units EU are, for example, disposed on the first surface of the substrate SB2 and electrically connected to the circuit layer CL, for example. In the present embodiment, the plurality of electronic units EU are light-emitting elements, but the disclosure is not limited thereto. The rest of the description about the plurality of electronic units EU is as provided in the above embodiments, and is not described again here.

In the present embodiment, in the normal direction n of the first surface SB2_S1 of the substrate SB2, the redundant region R2 of the linear polarizing film 110 is overlapped with the plurality of electronic units EU, and the functional region R1 of the linear polarizing film 110 is overlapped with the area of the substrate SB2 not covered by the plurality of electronic units EU. Since the redundant region R2 of the linear polarizing film 110 is the openings OP, the linear polarizing film 110 of the present embodiment may reduce the possibility of affecting the light emitted by the plurality of electronic units EU, thereby increasing the light extraction efficiency of the electronic device 10a of the present embodiment.

In the present embodiment, the electronic device 10a further includes an adhesive layer AL. The adhesive layer AL is, for example, disposed between the substrate SB1 and the substrate SB2 so that the substrate SB1 and the substrate SB2 are adhered to each other. The adhesive layer AL may include, for example, optical clear resin (OCR) or optical clear adhesive (OCA). For example, the material of the adhesive layer AL may include acrylic resin, silicone resin, epoxy resin, or other suitable materials or a combination of the above materials, but the disclosure is not limited thereto. In other embodiments, the electronic device 10a does not need to include the adhesive layer AL. That is, an air gap is included between the substrate SB1 and the substrate SB2.

FIG. 6B is a partial cross-sectional schematic diagram of an electronic device of the second embodiment of the disclosure. It should be mentioned that, the embodiment of FIG. 6B may adopt the reference numerals of the embodiment of FIG. 6A and a portion of the contents thereof, wherein the same or similar numerals are used to represent the same or similar elements and descriptions of the same technical contents are omitted.

Referring to FIG. 6B, the main difference between an electronic device 10b of the present embodiment and the electronic device 10a is that the electronic device 10b includes a color filter layer CF and does not include the plurality of patterned transparent patterns TP.

In detail, the color filter layer CF is, for example, located at a location where the plurality of patterned transparent patterns TP are originally disposed in the electronic device 10a. That is, the color filter layer CF is disposed on the first surface SB1_S1 of the substrate SB1. The color filter layer CF includes, for example, a plurality of filter units, and the filter units are overlapped with corresponding electronic units EU on the first surface SB2_S1 of the substrate SB2. Specifically, in the present embodiment, the color filter layer CF may include a red filter unit CF1, a green filter unit CF2, and a blue filter unit CF3 respectively overlapped with the red light-emitting unit EU1, the green light-emitting unit EU2, and the blue light-emitting unit EU3 in the normal direction n of the first surface SB2_S1 of the substrate SB2. Via the provision of the color filter layer CF, the ambient light irradiated to the electronic device 10b may be further absorbed, thereby improving the ambient light contrast of the electronic device 10b.

FIG. 6C is a partial cross-sectional schematic diagram of an electronic device of the third embodiment of the disclosure. It should be mentioned that, the embodiment of FIG. 6B may adopt the reference numerals of the embodiment of FIG. 6C and a portion of the contents thereof, wherein the same or similar numerals are used to represent the same or similar elements and descriptions of the same technical contents are omitted.

Please refer to FIG. 6C. The main difference between an electronic device 10c of the present embodiment and the electronic device 10b is that the electronic device 10c also includes a light-shielding structure BM.

The light-shielding structure BM is, for example, disposed on the substrate SB1, and overlapped with the circular polarizer in the normal direction n of the first surface SB2_S1 of the substrate SB2. In the present embodiment, the light-shielding structure BM and the circular polarizer 100 are stacked, and the circular polarizer 100 is disposed between the light-shielding structure BM and the substrate SB1. The light-shielding structure BM may, for example, include a light-shielding material. For example, the material of the light-shielding structure BM may include black resin or metal material having lower reflectivity, but the disclosure is not limited thereto.

FIG. 6D is a partial cross-sectional schematic diagram of an electronic device of the fourth embodiment of the disclosure. It should be mentioned that, the embodiment of FIG. 6D may adopt the reference numerals of the embodiment of FIG. 6C and a portion of the contents thereof, wherein the same or similar numerals are used to represent the same or similar elements and descriptions of the same technical contents are omitted.

Referring to FIG. 6D, the main difference between an electronic device 10d of the present embodiment and the electronic device 10b is that the electronic device 10d also includes a pixel definition layer PDL, a light conversion structure LS, and a scattering layer SC.

The pixel definition layer PDL is, for example, disposed on the first surface SB2_S1 of the substrate SB2, and disposed between adjacent electronic units EU. In some embodiments, the pixel definition layer PDL may be used to define the placement position in each of the plurality of electronic units EU, but the disclosure is not limited thereto. The pixel definition layer PDL may include, for example, a transparent material, a reflective material, or a light-shielding material. For example, the material of the pixel definition layer PDL may include an organic photoresist, but the disclosure is not limited thereto.

The light conversion structure LS is, for example, disposed on the surface SB1_S1 of the substrate SB1, and includes, for example, a barrier layer BANK, a wavelength conversion layer QDR, and a wavelength conversion layer QDG. In addition, in the present embodiment, each of the plurality of electronic units EU is a light-emitting unit emitting light of the same color. For example, each of the plurality of electronic units EU is the blue light-emitting unit EU3, but the disclosure is not limited thereto.

The barrier layer BANK is overlapped with the corresponding circular polarizer 100 in the normal direction n of the surface SB2_S1 of the substrate SB2, for example. In the present embodiment, the circular polarizer 100 is disposed between the barrier layer BANK and the substrate SB1. The barrier layer BANK may, for example, include a suitable organic material or an inorganic material, and the disclosure is not limited thereto.

The wavelength conversion layer QDR and the wavelength conversion layer QDG are overlapped with the corresponding filter units, for example, in the normal direction n of the first surface SB2_S1 of the substrate SB2, and are each stacked with the corresponding filter unit and light-emitting unit. In detail, in the present embodiment, the wavelength conversion layer QDR is overlapped with the red filter unit CF1 and the corresponding blue light-emitting unit EU3 in the normal direction n of the first surface SB2_S1 of the substrate SB2, and the wavelength conversion layer QDG is overlapped with the green filter unit CF2 and the corresponding blue light-emitting unit EU3 in the normal direction n of the first surface SB2_S1 of the substrate SB2. In some embodiments, the materials of the wavelength conversion layer QDR and the wavelength conversion layer QDG may each include a quantum dot material, a phosphorescent material, a fluorescent material, other suitable wavelength conversion materials, or a combination thereof. In other words, the wavelength conversion layer QDR and the wavelength conversion layer QDG may each convert the blue light emitted by the blue light-emitting unit EU3 into light having another wavelength. In the present embodiment, the colors of the light having another wavelength converted by each of the wavelength conversion layer QDR and the wavelength conversion layer QDG may roughly correspond to the colors of the red filter unit CF1 and the green filter unit CF2.

The scattering layer SC is also stacked, for example, with a corresponding circular polarizer 100. In the present embodiment, the scattering layer SCR is overlapped with the blue filter unit CF3 and the corresponding blue light-emitting unit EU3 in the normal direction n of the first surface SB2_S1 of the substrate SB2. In some embodiments, the scattering layer SC may include an organic material and a titanium dioxide particle located therein to scatter the blue light emitted by the blue light-emitting unit EU3, but the disclosure is not limited thereto.

FIG. 6E is a partial cross-sectional schematic diagram of an electronic device of the fifth embodiment of the disclosure. It should be mentioned that, the embodiment of FIG. 6E may adopt the reference numerals of the embodiments of FIG. 6C and FIG. 6D and a portion of the contents thereof, wherein the same or similar numerals are used to represent the same or similar elements and descriptions of the same technical contents are omitted.

Please refer to FIG. 6E. The main difference between an electronic device 10e of the present embodiment and the electronic device 10d is that the electronic device 10e also includes the light-shielding structure BM. The description about the light-shielding structure BM is as provided in the above embodiments, and is not described again here.

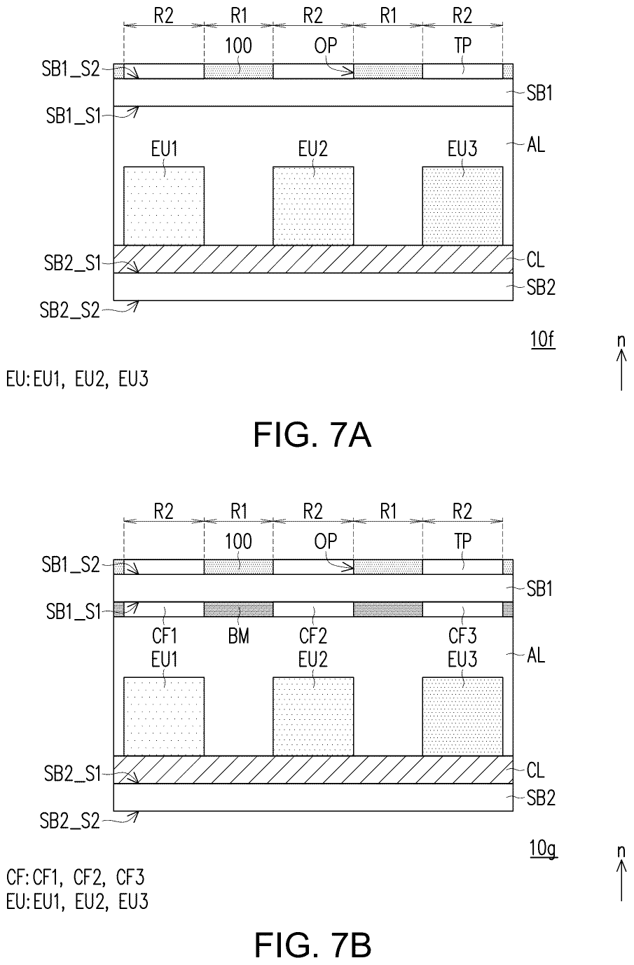

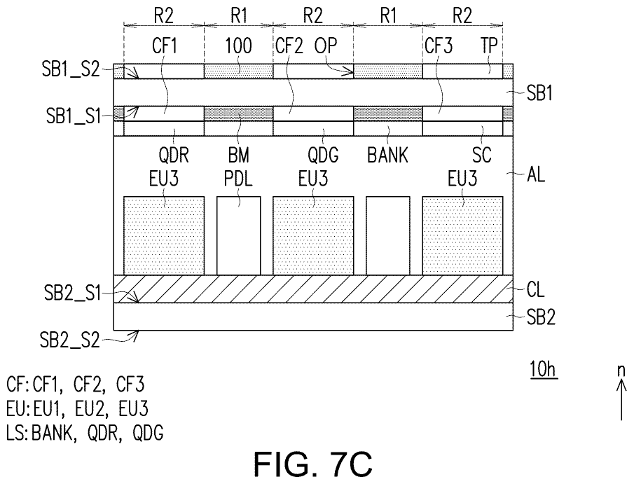

FIG. 7A is a partial cross-sectional schematic diagram of an electronic device of the sixth embodiment of the disclosure. It should be mentioned that, the embodiment of FIG. 7A may adopt the reference numerals of the embodiment of FIG. 6A and a portion of the contents thereof, wherein the same or similar numerals are used to represent the same or similar elements and descriptions of the same technical contents are omitted.

Referring to FIG. 7A, the main difference between an electronic device 10f of the present embodiment and the electronic device 10e is that the plurality of patterned transparent patterns TP and the circular polarizer 100 are disposed on the second surface SB1_S2 of the substrate SB1.

FIG. 7B is a partial cross-sectional schematic diagram of an electronic device of the seventh embodiment of the disclosure. It should be mentioned that, the embodiment of FIG. 7B may adopt the reference numerals of the embodiments of FIG. 7A and FIG. 6C and a portion of the contents thereof, wherein the same or similar numerals are used to represent the same or similar elements and descriptions of the same technical contents are omitted.

Referring to FIG. 7B, the main difference between an electronic device 10g of the present embodiment and the electronic device 10f is that the electronic device 10g further includes the color filter layer CF and the light-shielding structure BM disposed on the first surface SB1_S1 of the substrate SB1. The description about the color filter layer CF and the light-shielding structure BM is as provided in the above embodiments, and is not described again here.

FIG. 7C is a partial cross-sectional schematic diagram of an electronic device of the eighth embodiment of the disclosure. It should be mentioned that, the embodiment of FIG. 7C may adopt the reference numerals of the embodiments of FIG. 7B and FIG. 6E and a portion of the contents thereof, wherein the same or similar numerals are used to represent the same or similar elements and descriptions of the same technical contents are omitted.

Referring to FIG. 7C, the main differences between an electronic device 10h of the present embodiment and the electronic device 10g is that the electronic device 10h further includes the light conversion structure LS and the scattering layer SC disposed on the first surface SB1_S1 of the substrate SB1, and further includes the pixel definition layer PDL disposed on the first surface SB2_S1 of the substrate SB2. The description of the light conversion structure LS, the scattering layer SC, and the pixel definition layer PDL is as provided in the above embodiments and is not described again here.

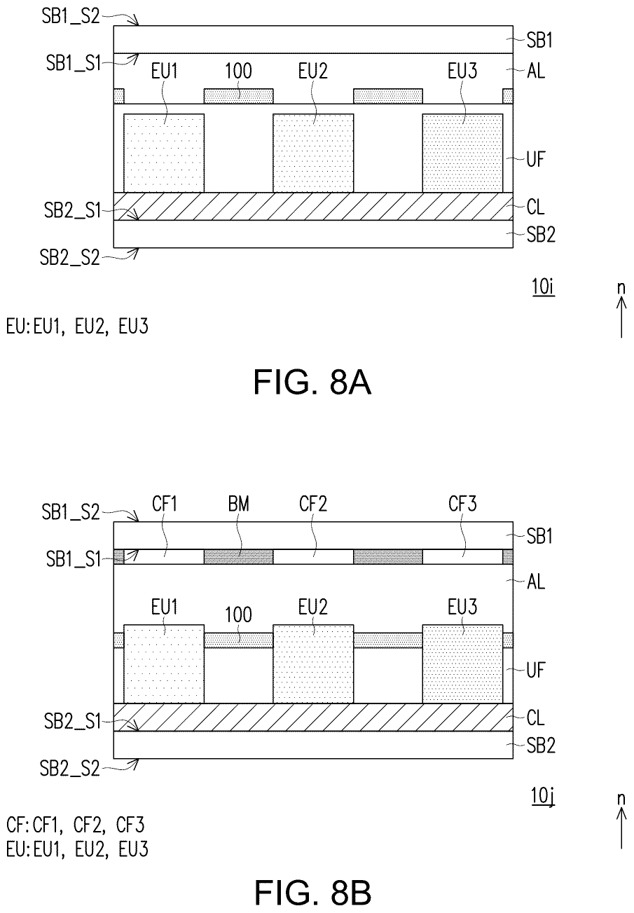

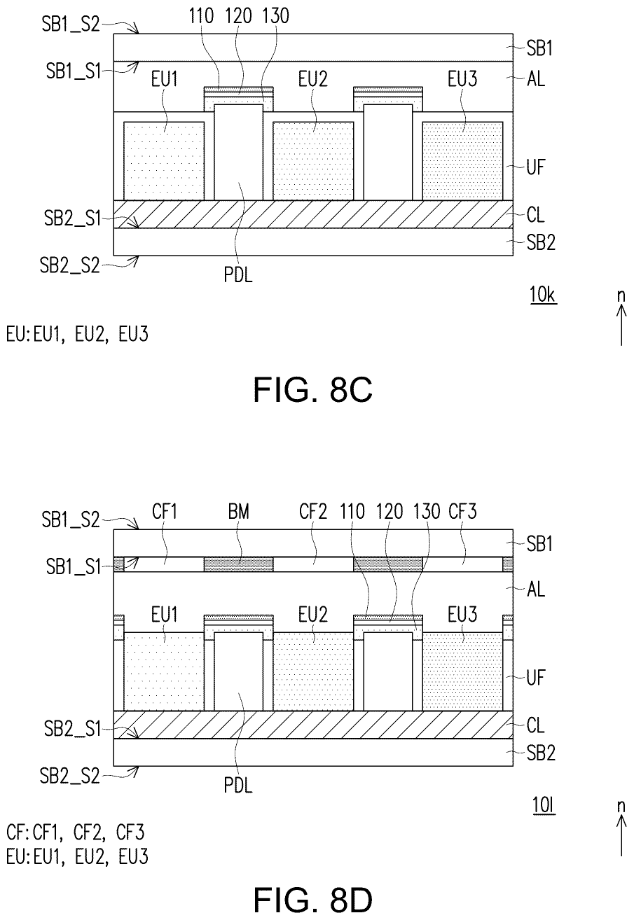

FIG. 8A is a partial cross-sectional schematic diagram of an electronic device of the ninth embodiment of the disclosure. It should be mentioned that, the embodiment of FIG. 8A may adopt the reference numerals of the embodiments of FIG. 6A and FIG. 5 and a portion of the contents thereof, wherein the same or similar numerals are used to represent the same or similar elements and descriptions of the same technical contents are omitted.

Please refer to FIG. 8A. In the present embodiment, the main difference between an electronic device 10i of the present embodiment and the electronic device 10a is that the electronic device 10i does not include the plurality of patterned transparent patterns TP, and the circular polarizer 100 is disposed on the first surface SB2_S1 of the substrate SB2.

In the present embodiment, the electronic device 10i further includes an underfill UF. The underfill UF is, for example, disposed on the circuit layer CL and covers the electronic units EU, for example, to protect the circuit layer CL and/or the electronic units EU. In addition, the underfill UF, for example, is filled in the openings between adjacent electronic units EU, for example, to fix the electronic units EU, but the disclosure is not limited thereto. The material of the underfill UF may include, for example, an optical clear resin. For example, the material of the underfill UF may include silicone resin, epoxy resin, or other suitable materials, or a combination of the above materials, but the disclosure is not limited thereto.

Accordingly, the circular polarizer 100 of the present embodiment is disposed on the underfill UF and located between adjacent electronic units EU. FIG. 8B is a partial cross-sectional schematic diagram of an electronic device of the tenth embodiment of the disclosure. It should be mentioned that, the embodiment of FIG. 8B may adopt the reference numerals of the embodiment of FIG. 8A and FIG. 6C and a portion of the contents thereof, wherein the same or similar numerals are used to represent the same or similar elements and descriptions of the same technical contents are omitted.

Referring to FIG. 8B, in the present embodiment, the main difference between an electronic device 10j of the present embodiment and the electronic device 10i is that the electronic device 10j further includes the color filter layer CF and the light-shielding structure BM disposed on the first surface SB1_S1 of the substrate SB1. The description about the color filter layer CF and the light-shielding structure BM is as provided in the above embodiments, and is not described again here.

In addition, in the present embodiment, the underfill UF is disposed on the circuit layer CL and located in the openings between adjacent electronic units EU, wherein the height of the top surface of the underfill UF is lower than the height of the top surface of the electronic units EU, but the disclosure is not limited thereto.

Accordingly, the circular polarizer 100 of the present embodiment is disposed on the underfill UF and located between adjacent electronic units EU.

FIG. 8C is a partial cross-sectional schematic diagram of an electronic device of the eleventh embodiment of the disclosure. It should be mentioned that, the embodiment of FIG. 8C may adopt the reference numerals of the embodiments of FIG. 8A and FIG. 6D and a portion of the contents thereof, wherein the same or similar numerals are used to represent the same or similar elements and descriptions of the same technical contents are omitted.

Referring to FIG. 8C, in the present embodiment, the main difference between an electronic device 10k of the present embodiment and the electronic device 10i is that the electronic device 10k further includes the pixel definition layer PDL disposed on the first surface SB2_S1 of the substrate SB2.

In the present embodiment, the pixel definition layer PDL is disposed in the openings between adjacent electronic units EU and located between the circular polarizer 100 and the substrate SB2 in the normal direction n of the substrate SB2. The description about the pixel definition layer PDL is as provided in the above embodiments, and is not described again here.

In addition, in the present embodiment, the underfill UF covers the electronic units EU and is filled in the gaps between adjacent electronic units EU and the pixel definition layer PDL. In detail, the underfill UF may have the shape of a three-sided square in the cross-sectional view of FIG. 8C to cover the electronic units EU. The height of the top surface of the underfill UF is, for example, lower than the height of the top surface of the pixel definition layer PDL, thereby exposing a portion of the side surface of the pixel definition layer PDL. In the present embodiment, the circular polarizer 100 is disposed on the exposed portion of the pixel definition layer PDL. In detail, the phase retardation film 130 of the circular polarizer 100 may have the shape of a three-sided square in the cross-sectional view of FIG. 8C to cover the exposed portion of the pixel definition layer PDL, and the intermediate layer 120 and the linear polarizing film 110 are sequentially disposed on the phase retardation film 130.

FIG. 8D is a partial cross-sectional schematic diagram of an electronic device of the twelfth embodiment of the disclosure. It should be mentioned that, the embodiment of FIG. 8D may adopt the reference numerals of the embodiments of FIG. 8C and FIG. 8B and a portion of the contents thereof, wherein the same or similar numerals are used to represent the same or similar elements and descriptions of the same technical contents are omitted.

Referring to FIG. 8D, in the present embodiment, the main difference between an electronic device 10l of the present embodiment and the electronic device 10k is that the electronic device 10l further includes the color filter layer CF and the light-shielding structure BM disposed on the first surface SB1_S1 of the substrate SB1. The description about the color filter layer CF and the light-shielding structure BM is as provided in the above embodiments, and is not described again here.

In addition, in the present embodiment, the underfill UF is disposed on the circuit layer CL and located in the gaps between adjacent electronic units EU and the pixel definition layer PDL. The height of the top surface of the underfill UF is, for example, lower than the height of the top surface of the pixel definition layer PDL, thereby exposing a side surface of a portion of the pixel definition layer PDL. In the present embodiment, the circular polarizer 100 is disposed on a portion of the pixel definition layer PDL exposed by the underfill UF. In detail, the phase retardation film 130 of the circular polarizer 100 may have the shape of a three-sided square in the cross-sectional view of FIG. 8D to cover the exposed portion of the pixel definition layer PDL, and the intermediate layer 120 and the linear polarizing film 110 are sequentially disposed on the phase retardation film 130.

Based on the above, the linear polarizing film in the circular polarizer included in the electronic device of some embodiments of the disclosure has the functional region and the redundant region, wherein the functional region is overlapped with the area not covered by the plurality of electronic units, and the redundant region is overlapped with the plurality of electronic units. The functional region of the linear polarizing film has the function of linearly polarizing light, and the redundant region of the linear polarizing film may reduce the impact on the light emitted by the plurality of electronic units. Via the arrangement of the circular polarizer, the functional region is not overlapped with the plurality of electronic units. Therefore, the light extraction efficiency of the electronic device of some embodiments of the disclosure may be improved, and the reflection of light by the circuit layer may be reduced.

Furthermore, the manufacturing method of the electronic device of some embodiments of the disclosure provides a novel forming method of the circular polarizer forming the linear polarizing film by drying and dyeing the lyotropic liquid-crystal composition. The lyotropic liquid-crystal composition may be patterned before or after drying to form the functional region and the redundant region respectively; or after drying, the exposed area of the lyotropic liquid-crystal composition may be dyed using the plurality of patterns to form the functional region and the redundant region respectively. Therefore, via the forming method of the circular polarizer, the electronic device manufactured via the manufacturing method of the electronic device of some embodiments of the disclosure may reduce the reflection of light by the circuit layer, and the light extraction efficiency thereof may be improved.

What is claimed is:

1. An electronic device, comprising:
a first substrate having a first surface;
a circuit layer disposed on the first surface;
a plurality of electronic units disposed on the first surface and electrically connected to the circuit layer; and
a circular polarizer comprising a phase retardation film and a linear polarizing film disposed on the phase retardation film, and the linear polarizing film comprises a functional region and a redundant region,
wherein in a normal direction of the first surface, the redundant region is overlapped with the plurality of electronic units, and the functional region is overlapped with an area of the first substrate not covered by the plurality of electronic units.

2. The electronic device of claim 1, wherein the phase retardation film comprises a lyotropic liquid crystal.

3. The electronic device of claim 1, wherein the linear polarizing film comprises a lyotropic liquid crystal and a dichroic dye.

4. The electronic device of claim 3, wherein the redundant region is an opening.

5. The electronic device of claim 3, wherein the redundant region is an undyed area.

6. The electronic device of claim 1, wherein the circular polarizer further comprises an intermediate layer disposed between the phase retardation film and the linear polarizing film.

7. The electronic device of claim 1, further comprising:
a second substrate having a second surface, wherein the second surface faces the first surface; and
a color filter layer disposed on the second surface of the second substrate, wherein the color filter layer comprises a plurality of filter units, and the plurality of filter units are overlapped with corresponding electronic units in the normal direction of the first surface.

8. The electronic device of claim 7, wherein the circular polarizer is disposed on the second surface of the second substrate.

9. The electronic device of claim 7, wherein the circular polarizer is disposed on a surface of the second substrate away from the first surface.

10. The electronic device of claim 1, further comprising:
a second substrate having a second surface, wherein the second surface faces the first surface; and
a plurality of patterned transparent patterns disposed on the second surface of the second substrate, wherein the plurality of patterned transparent patterns are overlapped with corresponding electronic units in the normal direction of the first surface.

11. The electronic device of claim 10, wherein the circular polarizer is disposed on the second surface of the second substrate.

12. The electronic device of claim 10, wherein the circular polarizer is disposed on a surface of the second substrate away from the first surface.

13. The electronic device of claim 7, further comprising:
a light-shielding structure disposed on the second surface of the second substrate, wherein the light-shielding structure is overlapped with the circular polarizer in the normal direction of the first surface.

14. The electronic device of claim 7, wherein each of the plurality of electronic units is a light-emitting unit emitting a light of a same color.

15. The electronic device of claim 14, further comprising:
a wavelength conversion layer disposed on the second surface of the second substrate, wherein the wavelength conversion layer is overlapped with a corresponding filter unit and a corresponding light-emitting unit in the normal direction of the first surface; and
a barrier layer disposed on the second surface of the second substrate, wherein the barrier layer is overlapped with the circular polarizer in the normal direction of the first surface.

16. The electronic device of claim 1, further comprising an underfill, wherein the underfill is disposed on the circuit layer.

17. The electronic device of claim 16, wherein the underfill covers the plurality of electronic units, and the circular polarizer is disposed on the underfill.

18. The electronic device of claim 16, wherein a height of a top surface of the underfill is lower than a height of a top surface of the plurality of electronic units.

19. The electronic device of claim 16, further comprising a pixel definition layer, wherein the pixel definition layer is disposed between adjacent electronic units.

20. The electronic device of claim 19, wherein the circular polarizer is disposed on the pixel definition layer.
